(19) United States
(12) Patent Application Publication
(10) Pub. No.: US 2008/0023319 A1
(43) Pub. Date: Jan. 31, 2008

(54) MAGNETRON ASSEMBLY

(76) Inventors: HIEN MINH HUU LE, San Jose, CA (US); Bradley O. Stimson, Monte Sereno, CA (US); Makoto Inagawa, Palo Alto, CA (US); John M. White, Hayward, CA (US)

Correspondence Address: PATTERSON & SHERIDAN, LLP, 3040 POST OAK BOULEVARD, SUITE 1500, HOUSTON, TX, 77056, US

(21) Appl. No.: 11/769,924

(22) Filed: Jun. 28, 2007

Related U.S. Application Data
(60) Provisional application No. 60/820,772, filed on Jul. 28, 2006.

(51) Int. Cl. C23C 14/35

(52) U.S. Cl. 204/192.1; 204/298.12; 204/298.16

(57) ABSTRACT

The present invention discloses a physical vapor deposition apparatus and a method for sputtering. When sputtering from a plurality of sputtering targets, a plurality of magnetrons may be used. The number of magnetrons may correspond to the number of targets. Each magnetron may be different to control the amount of material deposited from each sputtering target and the specific location on the sputtering target that is sputtered. The magnetrons may be spaced a different distance from the backing plate and hence, the target. The magnetrons may be of different sizes. The magnetrons may have a different magnetic path. The magnetrons may have a different pitch. The magnetrons may have a different magnitude. By tailoring the distance, size, path, pitch, and magnitude, uniform sputtering and target erosion may be achieved.

### CROSS-REFERENCE TO RELATED APPLICATIONS

This application claims benefit of U.S. provisional patent application Ser. No. 60/820,772 (APPM/11274L), filed Jul. 28, 2006, which is herein incorporated by reference.

### BACKGROUND OF THE INVENTION

1. Field of the Invention

Embodiments of the present invention generally relate to a magnetron for a physical vapor deposition (PVD) apparatus.

2. Description of the Related Art

PVD using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (e.g., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

A magnetron may be used in sputtering to confine a large number of the ions in a magnetic field. By confining a large number of the ions, the amount of material sputtered may be increased in the area encompassed by the magnetic field because a greater number of ions may collide with the sputtering target and sputter atoms from the target. By confining a large number of ions, a high density plasma may be created that may increase the sputtering rate.

There is a need in the art for an improved magnetron that can increase the sputtering rate and increase the target erosion uniformity.

### SUMMARY OF THE INVENTION

The present invention generally discloses a PVD apparatus and a method for sputtering. When sputtering from a plurality of sputtering targets, a plurality of magnetrons may be used. The number of magnetrons may correspond to the number of targets. Each magnetron may be different to control the amount of material deposited from each sputtering target and the specific location on the sputtering target that is sputtered. The magnetrons may be spaced a different distance from the backing plate and hence, the target. The magnetrons may be of different sizes. The magnetrons may have a different magnetic path. The magnetrons may have a different pitch. The magnetrons may have a different magnitude. By tailoring the distance, size, path, pitch, and magnitude, uniform sputtering and target erosion may be achieved.

In one embodiment, a physical vapor deposition apparatus is disclosed. The apparatus comprises a first sputtering target assembly having a first sputtering target and a first backing plate coupled therewith, a first magnetron positioned adjacent the first backing plate, the first magnetron spaced a first distance from the first backing plate, a second sputtering target assembly having a second sputtering target and a second backing plate coupled therewith, and a second magnetron positioned adjacent the second backing plate, the second magnetron spaced a second distance from the second backing plate, the first distance is greater than the second distance.

In another embodiment, a physical vapor deposition apparatus is disclosed. The apparatus comprises a first sputtering target assembly having a first sputtering target and a first backing plate coupled therewith, a first magnetron positioned adjacent first backing plate, the first magnetron having a first size, a second sputtering target assembly having a second sputtering target and a second backing plate coupled therewith, and a second magnetron positioned adjacent the second backing plate, the second magnetron having a second size, the first size is greater than the second size.

In another embodiment, a physical vapor deposition apparatus is disclosed. The apparatus comprises a first sputtering target assembly having a first sputtering target and a first backing plate coupled therewith, a first magnetron positioned adjacent first backing plate, the first magnetron configured to create a first magnetic track pattern, a second sputtering target assembly having a second sputtering target and a second backing plate coupled therewith, and a second magnetron positioned adjacent the second backing plate, the second magnetron configured to create a second magnetic track pattern, the first magnetic track pattern is different from the second magnetic track pattern.

In another embodiment, a physical vapor deposition apparatus is disclosed. The apparatus comprises a first sputtering target assembly having a first sputtering target and a first backing plate coupled therewith, a first magnetron positioned adjacent first backing plate, the first magnetron having a first pitch, a second sputtering target assembly having a second sputtering target and a second backing plate coupled therewith, and a second magnetron positioned adjacent the second backing plate, the second magnetron having a second pitch, the first pitch is different from the second pitch.

In another embodiment, a physical vapor deposition apparatus is disclosed. The apparatus comprises a first sputtering target assembly having a first sputtering target and a first backing plate coupled therewith, a first magnetron positioned adjacent first backing plate, the first magnetron having a first magnitude, a second sputtering target assembly having a second sputtering target and a second backing plate coupled therewith, and a second magnetron positioned adjacent the second backing plate, the second magnetron having a second magnitude, the first magnitude is different from the second magnitude.

In another embodiment, a sputtering method is disclosed. The method comprises positioning first and second target assemblies in a sputtering chamber, each target assembly having a sputtering target with a sputtering surface, creating a first magnetic field, the first magnetic field extending a first distance past the first sputtering surface, creating a second magnetic field, the second magnetic field extending a second distance past the second sputtering surface, the second distance is shorter than the first distance, and applying a bias to the first and second sputtering target assemblies to sputter material.

In another embodiment, a sputtering method is disclosed. The method comprises positioning first and second target assemblies in a sputtering chamber, each sputtering target assembly having a sputtering target with a sputtering surface, moving a first magnetron a first distance, the first magnetron positioned behind the first sputtering target assembly, moving a second magnetron a second distance, the second magnetron positioned behind the second target assembly, the first distance is greater than the second distance, and applying a bias to the first and second sputtering target assemblies to sputter material.

In another embodiment, a sputtering method is disclosed. The method comprises positioning first and second target assemblies in a sputtering chamber, each target assembly having a sputtering target with a sputtering surface, creating a first magnetic field track across the first sputtering surface, creating a second magnetic field track across the second sputtering surface, the first magnetic field track and the second magnetic field track each have different shapes, and applying a bias to the first and second sputtering target assemblies to sputter material.

In another embodiment, a sputtering method is disclosed. The method comprises positioning first and second target assemblies in a sputtering chamber, each target assembly having a sputtering target with a sputtering surface, creating a first magnetic field, the first magnetic field having a first pitch, creating a second magnetic field, the second magnetic field having a second pitch, the second pitch is shorter than the first pitch, and applying a bias to the first and second sputtering target assemblies to sputter material.

In another embodiment, a sputtering method is disclosed. The method comprises positioning first and second target assemblies in a sputtering chamber, each target assembly having a sputtering target with a sputtering surface, creating a first magnetic field, the first magnetic field having a first magnitude, creating a second magnetic field, the second magnetic field having a second magnitude, the second magnitude is less than the first magnitude, and applying a bias to the first and second sputtering target assemblies to sputter material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PVD apparatus 100 according to one embodiment of the invention.

FIG. 2 is a top view of a magnetron assembly 200 according to one embodiment of the present invention.

FIG. 3A is a cross sectional view of a PVD apparatus 300 according to another embodiment of the invention.

FIG. 3B is a cross sectional view sowing the magnetic field B created in the PVD apparatus 300 of FIG. 3A.

FIG. 4 is a top view of a magnetron assembly 400 according to another embodiment of the invention.

FIG. 5 is a top view of a magnetron assembly 500 according to yet another embodiment of the invention.

FIG. 6 is a top view of a magnetron assembly 600 according to still another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally discloses a PVD apparatus and a method for sputtering. When sputtering from a plurality of sputtering targets, a plurality of magnetrons may be used. The number of magnetrons may correspond to the number of targets. Each magnetron may be different to control the amount of material deposited from each sputtering target and the specific location on the sputtering target that is sputtered. The magnetrons may be spaced a different distance from the backing plate and hence, the target. The magnetrons may be of different sizes. The magnetrons may have a different magnetic path. The magnetrons may have a different pitch. The magnetrons may have a different magnitude. By tailoring the distance, size, path, pitch, and magnitude, uniform sputtering and target erosion may be achieved.

The invention is illustratively described and may be used in a PVD system for processing large area substrates, such as a PVD system, available from AKT®, a subsidiary of Applied Materials, Inc., Santa Clara, Calif. However, it should be understood that the sputtering target may have utility in other system configurations, including those systems configured to process large area round substrates. An exemplary system in which the present invention may be practiced is described in U.S. patent application Ser. No. 11/225,922, filed Sep. 13, 2005, which is hereby incorporated by reference in its entirety.

As the demand for larger flat panel displays increases, so must the substrate size. As substrate size increases, so must the size of the sputtering target. For flat panel displays and solar panels, sputtering targets having a length of greater than 1 meter are not uncommon. Producing a unitary sputtering target of substantial size from an ingot can prove difficult and expensive. For example, it is difficult to obtain large molybdenum plates (i.e., 1.8 m×2.2 m×10 mm, 2.5 m×2.8 m×10 mm, etc.) and quite expensive. Producing a large area molybdenum target requires a significant capital investment. A large area (i.e., 1.8 m×2.2 m×10 mm) one piece molybdenum target may cost as much as $15,000,000 to produce. Therefore, for cost considerations alone, it would be beneficial to utilize a plurality of smaller targets, but still achieve the deposition uniformity of a large area sputtering target. The plurality of targets may be the same composition or a different composition.

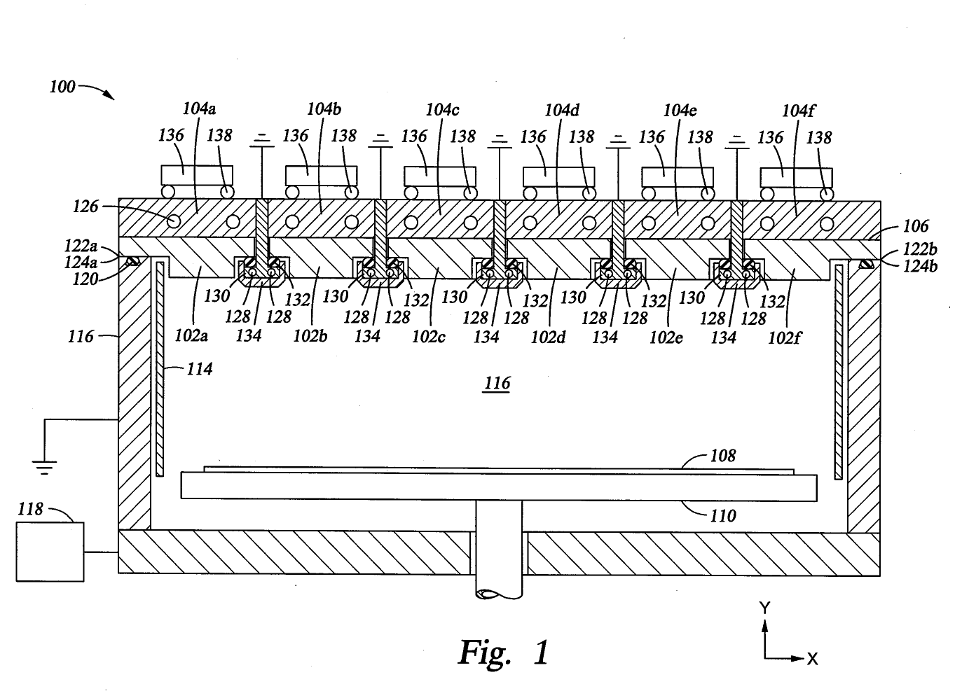

When utilizing a plurality of sputtering targets, it may be beneficial to have a corresponding magnetron for each target. FIG. 1 is a cross sectional view of a PVD apparatus 100 according to one embodiment of the invention that utilizes a plurality of sputtering targets 102a-102f, each with a corresponding magnetron 136. Each sputtering target 102a-102f may be coupled with a backing plate 104a-104f with a bonding layer 106 coupled between. A substrate 108 may be positioned on a susceptor 110 across a processing space 116. The chamber walls 112 of the apparatus 100 may be shielded by a shield 114 that circumscribes the processing space 116. The edge sputtering targets 102a, 102f may form a seal with the chamber walls 112 by a sealing member 120, and sealing surfaces 122a, 122b, 124a, 124b. In one embodiment, the sealing member 120 may be an O-ring. A controller 118 may control any movement of the susceptor, movement of the magnetrons 136 and bias applied to the targets 102a-102f.

Each backing plate 104a-104f may have one or more cooling channels 126 formed therein. The cooling channels may control the temperature of the backing plates 104a-104f as well as the sputtering targets 102a-102f. By controlling the temperature of the sputtering targets 102a-102f, any expansion and contraction due to temperature changes may be reduced.

It is to be understood that while six sputtering targets 102a-102f with corresponding backing plates 104a-104f have been shown in FIG. 1, more or less sputtering targets 102a-102f and backing plates 104a-104f may be utilized. In one embodiment, a single backing plate may be used with a plurality of sputtering targets coupled therewith.

An anode 130 may be positioned between adjacent sputtering targets 102a-102f. As may be seen in FIG. 1, the anodes may be grounded. The anode 130 may be shielded from any sputter deposition by a shield 134. The anodes 130 may be electrically isolated from the sputtering targets 102a-102f by a sealing member 132. In one embodiment, the sealing member 132 may be an O-ring. The anode 130 may also comprise one or more cooling channels 128. The cooling channels 128 may control the temperature of the anode 130 as well as the shield 134. By controlling the temperature of the anode 130 and thus, the shield 128, any expansion and contraction of the shield 128 and the anode 130 may be reduced. By reducing the expansion and contraction of the anode 130 and the shield 128, flaking may be reduced. Flaking occurs when material deposited on a surface flakes off and thus, contaminate a substrate 108. Flaking may occur as a result of expansion and contraction of the surface upon which material is deposited.

Each magnetron 136 may have one or more rollers 138 upon which the magnetron 136 may move across a surface of the backing plate 104a-104f. The rollers 138 permit the magnetrons 136 to translate across the backing plate 104a-104f within a plane. By translating a magnetron 136 across the back surface of the backing plate 104a-104f, the magnetic field created by the magnetron 106 may translate across the sputtering target 102a-102f. By translating the magnetic field across the sputtering target 102a-102f, material may be sputtered from a greater area of the targets 102a-102f.

As material is sputtered from the sputtering targets 102a-102f, the sputtering targets 102a-102f are considered to be “eroding”. By translating the magnetrons 136 and hence, the magnetic field, atoms may be sputtered from different areas of the sputtering target 102a-102f. Controlling the translation of the magnetron 136 may enable a technician to ensure that the target 102a-102f is uniformly eroded. For example, as more material is sputtered from a particular location on the sputtering target 102a-102f, the magnetron 136 may be translated and hence, translate the magnetic field. The magnetic field may be translated to a location on the sputtering target 102a-102f where less material has been sputtered. Thus, translating the magnetron 136 across the back of the backing plate 104a-104f may permit more uniform target 102a-102f erosion and hence, a longer target 102a-102f life.

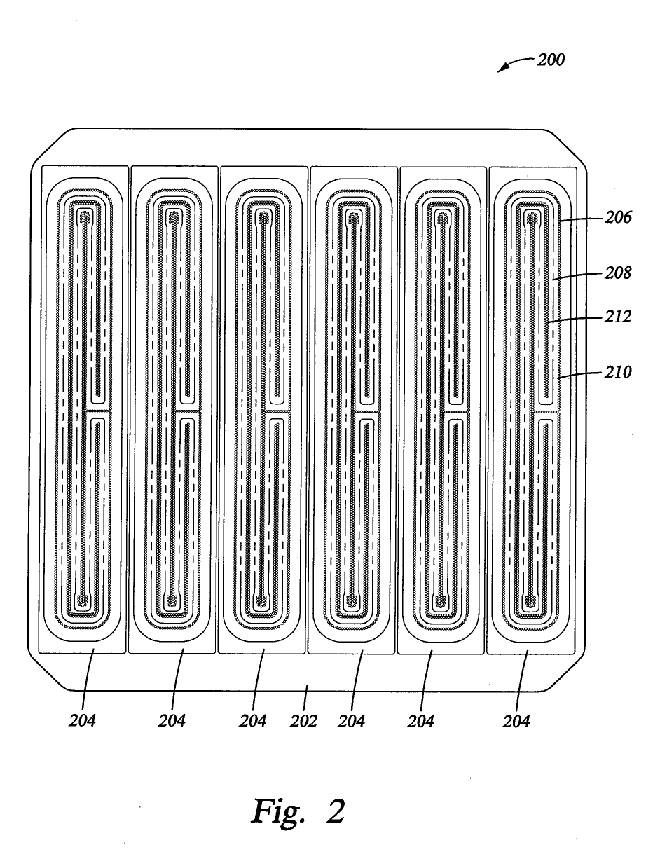

FIG. 2 is a top view of a magnetron assembly 200 according to one embodiment of the present invention. A plurality of magnetrons 204 may be spaced across the back surface of a backing plate assembly 202. Each magnetron 204 may comprise a plurality of magnets 206. In one embodiment, the magnets 206 may be cylindrical magnets. In another embodiment, the magnets 206 may be bar shaped magnets. In yet another embodiment, some of the magnets 206 may be cylindrical and some of the magnets may be bar shaped. Each of the magnetrons 204 creates a magnetic field track 208.

The magnets 206 may be positioned across the magnetron 204 in an arrangement to create the magnetic field track 208 between adjacent magnet arrays. For example a plurality of magnets 206 may be coupled together to create a first magnet array 210. Additionally, another plurality of magnets 206 may be coupled together to create a second magnet array 212. In one embodiment, the two magnet arrays 210, 212 are magnetically isolated from one another so that one magnetic array 210 may be positioned with the north pole oriented downwards towards the backing plate assembly 202 and the second magnetic array 212 may be positioned with the south pole oriented downwards towards the backing plate assembly 202. Thus, the magnetic field track may be created in an area between the magnetic arrays 210, 212. The spacing between the magnetic arrays 210, 212 is referred to as the pitch.

The layout of the magnetic arrays 210, 212 and the relation of the magnetic arrays 210, 212 to each other determines the shape of the magnetic field track 208. As shown in FIG. 2, the magnetic arrays 210, and 212 for each magnetron 204 may be positioned to create a magnetic field track 208 having multiple turns.

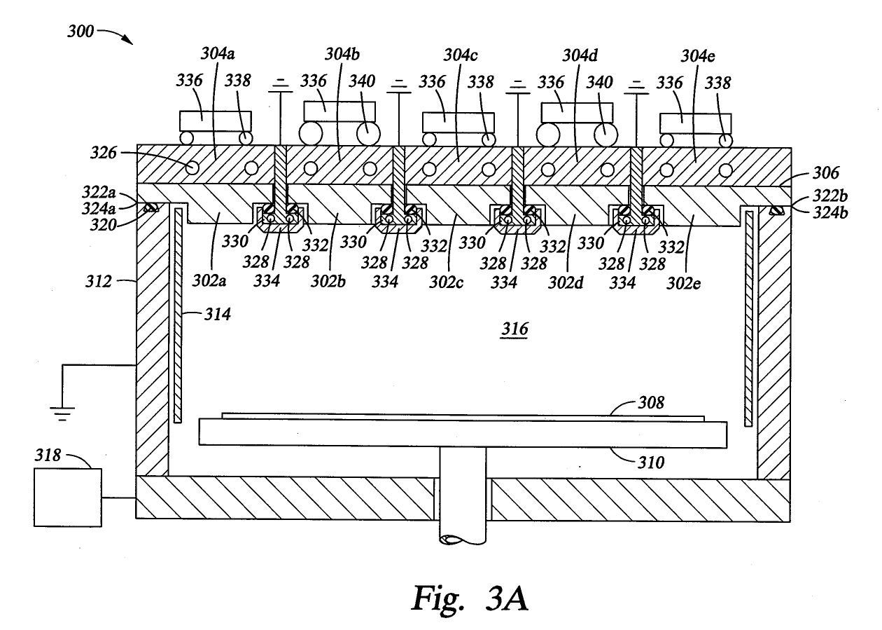

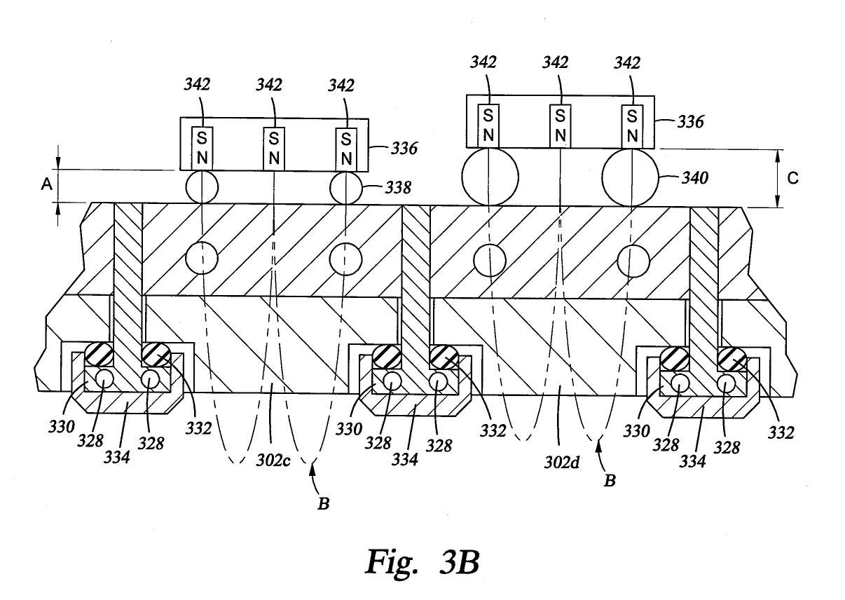

FIG. 3A is a cross sectional view of a PVD apparatus 300 according to another embodiment of the invention. The apparatus 300 may comprise a plurality of targets 302 coupled with a backing plate 304 by a bonding layer 306. The sputtering targets 302 may be spaced across a processing space 316 from a substrate 308 that may be positioned on a susceptor 310. The chamber walls 312 may be protected from deposition by a shield 314. A controller 318 may control the movement of the susceptor 308, the power applied to each sputtering target 302 and the flow of processing gas into the apparatus 300.

The sputtering targets 302 seal to the chamber walls 312 using a sealing member 320. In one embodiment, the sealing member 320 may be an O-ring. A sealing surface 322a, 322b of the target 302 may couple with a sealing surface 324a, 324b of the chamber 312 during sealing.

One or more cooling channels 326 may be present in the backing plate 304. The cooling channels 326 may reduce expansion and contraction of the backing plate 304 and the sputtering targets 302. The sputtering targets 302 may be separated by an anode 330. Each anode 330 may have one or more cooling channels 328 therein to reduce expansion and contraction of the anode 330 and protective shield 334. By reducing the expansion and contraction of the shield 334, flaking may be reduced. The anode 330 may be electrically insulated from the sputtering targets 302 by a sealing member 332. In one embodiment, the sealing member 332 may be an O-ring.

A magnetron 336 may be positioned in back of each backing plate 304. The magnetrons 336 may be translated across the back surface of the backing plate 304 by rollers 338, 340.

FIG. 3B is a cross sectional view showing the magnetic field B created in the PVD apparatus 300 of FIG. 3A. As may be seen from FIG. 3B, the rollers 338, 340 for each magnetron 336 may be of a different size. By utilizing rollers 338, 340 having different sizes, the magnetrons 336 may be spaced closer or further away from the backing plate 304. As may be seen in FIG. 3B, rollers 340 space the magnetron 336 from the backing plate 304 by a distance C. Rollers 338 space the magnetron 336 from the backing plate 304 by a distance A. Because rollers 340 have a larger diameter than rollers 338, rollers 340 may space the magnetron 336 a greater distance away from the backing plate 304 than rollers 338. Therefore, the distance C is greater than the distance A.

The magnets 342 within the magnetron 336 create the magnetic field B that extends into the processing space 316. As may be seen from FIG. 3B, because rollers 340 position the magnetron 336 a greater distance away from the backing plate 304 than do rollers 338, the magnetic field B associated with the magnetron 336 spaced by rollers 340 may not extend as far into the processing space 316 as the magnetic field B generated by the magnetron 336 spaced from the backing plate 304 by rollers 338.

By adjusting the spacing between the backing plate 304 and the magnetron 336, the magnetic field B may be controlled. The magnetic field B may be controlled so that the amount of material sputtered from the sputtering targets 302 may also be controlled. The amount of material sputtered from the targets 302 may vary from target 302 to target 302. By creating a greater distance between the backing plate 304 and the magnetron 336, the plasma density in front of the target 302 may not be as high and thus, a lower sputtering rate from the target 302 may occur. Conversely, when the magnetron 336 is spaced closer to the backing plate 304 and the magnetic field B extends further into the processing space 316, a higher density of plasma may be formed in front of the sputtering target 302 and thus, increase the sputtering rate.

In one embodiment, all of the magnetrons 336 may be spaced an equal distance from the backing plate 304. In another embodiment, each magnetron 336 may be spaced from the backing plate 304 by a different distance. In yet another embodiment, the magnetrons 336 for the targets 302 that correspond to the edge of the substrate 308 may be spaced a further distance away from the backing plate 304 then the magnetrons 336 corresponding to the backing plates 304 located above the center of the substrate 308. By controlling the spacing of the magnetrons 336 from the backing plate 304 and hence, the extension of the magnetic field B into the processing space 316, the amount of sputtering from each individual sputtering target 302 may be tailored to suit the particular needs of a particular process.

It is to be understood that any combination of magnetron 336 spacing may be utilized. In one embodiment, the magnetrons 336 may each be spaced an equal distance from the backing plate 304. In another embodiment, each magnetron 336 may be spaced a different distance from the backing plate 304. In yet another embodiment, some magnetrons 336 may be spaced an equal distance from the backing plate 304 while other magnetrons 336 may be spaced a greater distance from the backing plate 304.

Additionally, while only five sputtering targets 302, backing plates 304, and magnetrons 336 have been shown, more or less targets 302, backing plates 304, and magnetrons 336 may be used. In one embodiment, a single backing plate 304 may be used while a plurality of sputtering targets 302 may be coupled with the backing plate 304.

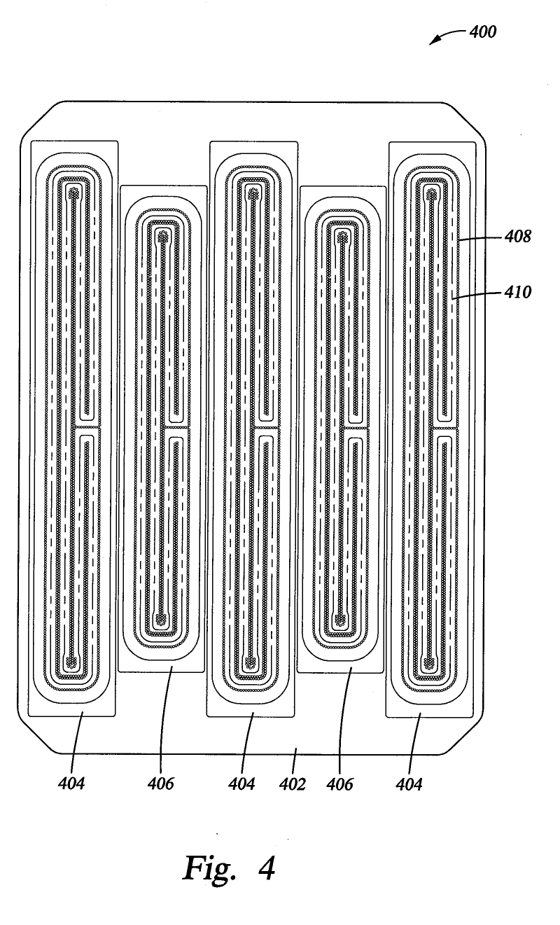

FIG. 4 is a top view of a magnetron assembly 400 according to another embodiment of the invention. A plurality of magnetrons 404, 406 may be spaced across a backing plate assembly 402. Each magnetron 404, 406 may have a plurality of magnets 408 therein. In one embodiment, the magnets may be cylindrical magnets. In another embodiment, the magnets 408 may be bar shaped magnets. In yet another embodiment, some of the magnets 408 may be cylindrical and some of the magnets may be bar shaped. Each of the magnetrons 404, 406 creates a magnetic field track 410.

As may be seen from FIG. 4, the magnetrons 404, 406 may have a different size. In the embodiment shown in FIG. 4, three magnetrons 404 are larger than two other magnetrons 406. The size of the magnetrons 404, 406 may also affect the sputtering rate. By having a smaller magnetron 406 over the backing plate assembly 402, a magnetic field may extend into the processing space over a smaller area of the sputtering target (not shown). As discussed above, a high density plasma may form in the magnetic field in front of the sputtering target and hence, increase the sputtering rate. Because a smaller magnetron 406 may be used, a smaller area of the sputtering target may be exposed to a high density plasma. Because a smaller area of the exposed to a high density plasma, the sputtering rate at various locations across a sputtering target may be different and thus, controlled.

It is to be understood that while five magnetrons 404, 406 have been shown in FIG. 4, more or less magnetrons 404, 406 may be used. Additionally, each of the magnetrons 404, 406 may be of the same or different size. When a combination of smaller and larger magnetrons 404, 406 is used, the smaller magnetrons 406 may be placed at any location, depending upon the desired deposition parameters. Likewise, the larger magnetrons 404 may be placed at any location, depending upon the desire deposition parameters.

If more deposition is desired at the center of the substrate (i.e., to compensate for a high deposition rate occurring at the edge of the substrate), smaller magnetrons 406 may be used in an area corresponding to the center of the substrate to create a higher density plasma in front of the sputtering targets at an area corresponding to the center of the substrate. Therefore, more deposition may occur from areas of the targets corresponding to the center of the substrate and less deposition may occur from the areas of the targets corresponding to the edge areas of the substrate.

By adjusting the size of the magnetrons 404, 406, the amount of deposition occurring from each individual target, and the specific areas of the individual targets may be controlled to help ensure uniform deposition.

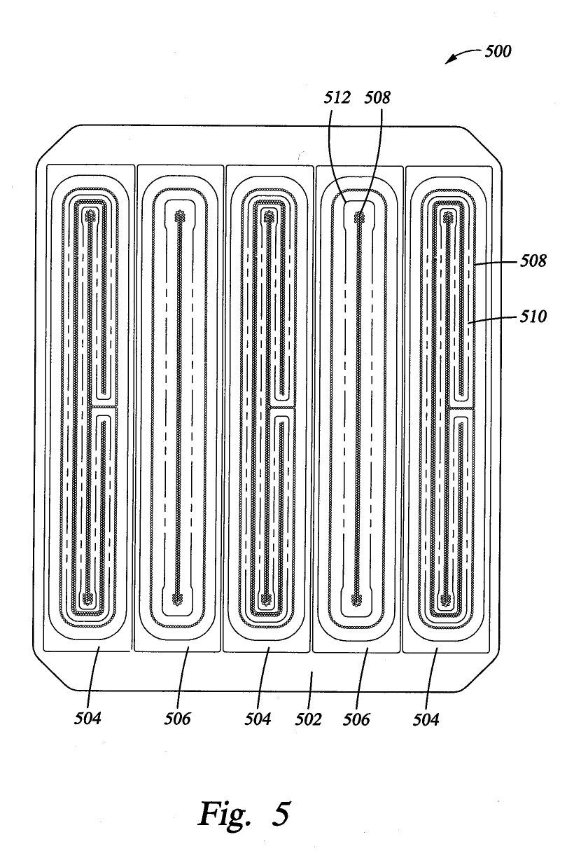

FIG. 5 is a top view of a magnetron assembly 500 according to yet another embodiment of the invention. The magnetron assembly 500 may comprise a plurality of magnetrons 504, 506 spaced across a backing plate assembly 502. Each magnetron 504, 506 may have a plurality of magnets 508 therein. In one embodiment, the magnets 508 may be cylindrical magnets. In another embodiment, the magnets 508 may be bar shaped magnets. In yet another embodiment, some of the magnets 508 may be cylindrical and some of the magnets may be bar shaped. Each of the magnetrons 508 creates a magnetic field track 510, 512.

As may be seen in FIG. 5, the magnetrons 504, 506 may have different shaped magnetic field tracks 510, 512. In the embodiment depicted in FIG. 5, three of the magnetrons 504 have a multi-turn magnetic field track 510 and two of the magnetrons 506 have a racetrack shape magnetic field track 512. It is to be understood that the shape of the magnetic field tracks 510, 152 is not limited. Any suitable magnetic field track shape may be utilized.

By utilizing a different magnetic field track 510, 512 for the magnetrons 504, 506, the magnetic field extending into the process space may be controlled and hence, the sputtering rate and the particular areas of the sputtering target being sputtered, may be controlled. When utilizing the magnetron 504 having the multi-turn magnetic field track 510, the magnetic field track 510 may be smaller and tighter (i.e., the track may be pinched close together) and hence, a high density plasma may be formed to produce a high sputtering rate. Similarly, when utilizing magnetrons 506 having the racetrack shaped magnetic field track 512, the magnetic field track 512 may be wider (when compared to the magnetic field track 510) and hence spread across a wider area of the sputtering target. By spreading across a wider area of the sputtering target, the plasma density for the racetrack magnetic field track 512 may not be as high as the plasma density for the multi-turn magnetic field track 510. Because the racetrack magnetic field track 512 may have a lower plasma density than the multi-turn magnetic field track 510, the sputtering rate from the targets corresponding to magnetrons 506 may be lower. Thus, by adjusting the magnetic field track 510, 512, the sputtering rate may be controlled.

It is to be understood that while five magnetrons 504, 506 have been exemplified in FIG. 5, more or less magnetrons 504, 506 may be used. Additionally, any arrangement of magnetrons 504, 506 may be used. In particular, each magnetron 504, 506 may have the same or different magnetic field track 510, 512. The magnetic field track 510, 512 is not to be limited to a multi-turn magnetic field track 510, or a racetrack shaped magnetic field track 512 as other shaped magnetic field tracks are also contemplated.

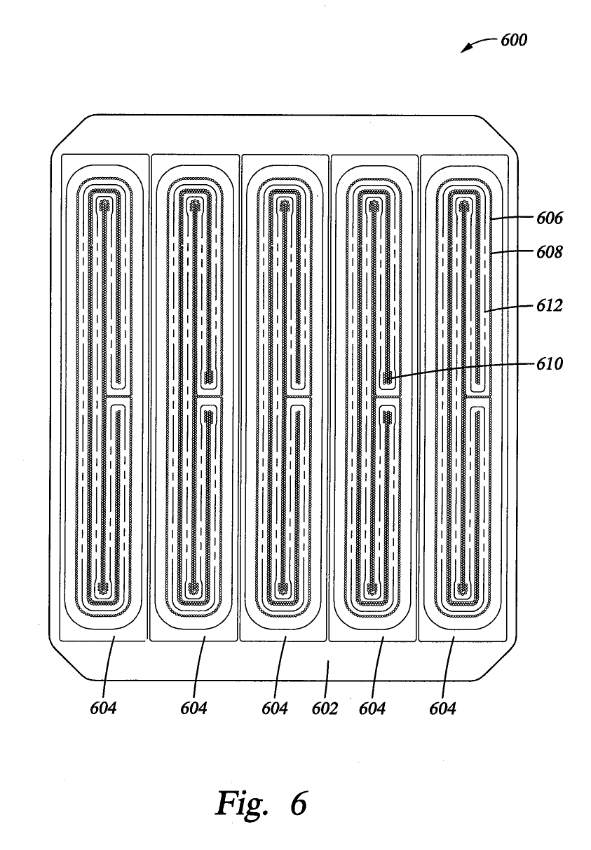

FIG. 6 is a top view of a magnetron assembly 600 according to still another embodiment of the invention. The magnetron assembly 600 may comprise a plurality of magnetrons 604 positioned over a backing plate assembly 602. Each magnetron 604 may comprise a plurality of magnets 606. In one embodiment, the magnets 606 may be cylindrical magnets. In another embodiment, the magnets 606 may be bar shaped magnets. In yet another embodiment, some of the magnets 606 may be cylindrical and some of the magnets may be bar shaped. Each of the magnetrons 606 creates a magnetic field track 608.

As may be seen from FIG. 6, two of the magnetrons 604 have a tear drop shaped portion 610 that is different from the other magnetrons 604. The tear drop portion 610 may comprise a higher density of magnets 606. The higher density of magnets 606 may change the pitch of the magnetic field track 608 in the area near the tear drop portion 610. By increasing the density of magnets 606 congregated at the tear drop portion 610 of the magnetron 604, the magnetic field track 608 may pinch closer together near the tear drop portion 610 and hence, create a higher density plasma in front of the sputtering target. By pinching the magnetic field track 608, the pitch has been adjusted.

In another embodiment, the spacing or pitch between the magnet arrays 612, 614 may be adjusted. The magnet arrays 612, 614 may be set at a fixed location so that the pitch is fixed or the magnet arrays 612, 614 may be moveable so that the pitch may be adjusted to suit the needs of the particular process.

It is to be understood that while five magnetrons 604 have been shown in FIG. 6, more or less magnetrons 604 may be used. Additionally, each magnetron 604 may have the same pitch or tear drop portion 610. Alternatively, each magnetron 604 may have a different pitch or tear drop portion 610. Combinations of magnetrons 604 in which some have the same pitch or tear drop portion 610 and others have different pitches or tear drop portions 610 is also contemplated.

It is also to be understood that the additional magnets need not be placed solely in the tear drop portion 610 of the magnetron 604. Additional magnets 606 may be placed or removed from other locations of the magnetron 604. Thus, the arrangement of the magnets 606 may be adjusted to create the desired magnetic field. In one embodiment, each magnetron 604 has a different magnet 606 configuration. In another embodiment, each magnetron 604 has the same magnet 606 configuration. In yet another embodiment, some of the magnetrons 604 have identical magnet 606 configurations and other magnetrons 604 have different magnet 606 configurations.

The magnitude of the magnets used in the magnetron may also be adjusted. In one embodiment, all of the magnets in the magnetron may be of the same magnitude. In another embodiment, weaker magnets may be used near the turns of the magnetic field track while stronger magnets may be used in the straight portions of the magnetic field track.

At the turns of a magnetic field track, the plasma density tends to be higher than at other locations on the magnetic field track (assuming magnets of equal magnitude are utilized). Therefore, the target may erode at a faster rate in the area corresponding to the magnetic field track turn than in the other areas of the target. The faster that the target erodes, the sooner that it may need to be replaced. When a specific area of a target erodes at a faster rate than another area of a target, the target erodes non-uniformly and hence, is not efficiently utilized. By placing weaker magnets near the turns of the magnetic field track, the strength of the magnetic field at the turn may be adjusted to compensate for the higher density plasma. The weaker magnets may cause the density at the turn of the magnetic field track to be equivalent to the density produced at all other areas. Therefore, adjusting the magnitude of the magnets may control the magnetic field and improve target erosion uniformity.

It is to be understood that various combinations of magnetron to backing plate distance, magnetron size, magnetic field track length, pitch, and magnitude may be selected based upon the needs of the particular process. In one embodiment, each magnetron may be identical. In another embodiment, each magnetron may be different. In yet another embodiment, some magnetrons may be identical and other magnetrons may be different. The different magnetrons may be different due to the magnetron to backing plate distance, magnetron size, magnetic field track length, pitch, and/or the magnitude of the magnets. Thus, any of the above described magnetron configurations are contemplated to be used in any combination.

While the foregoing is directed to embodiments of the present invention, other and further embodiments of the invention may be devised without departing from the basic scope thereof, and the scope thereof is determined by the claims that follow.

1. A physical vapor deposition apparatus, comprising:
a first sputtering target assembly having a first sputtering target and a first backing plate coupled therewith;
a first magnetron positioned adjacent the first backing plate, the first magnetron spaced a first distance from the first backing plate;
a second sputtering target assembly having a second sputtering target and a second backing plate coupled therewith; and
a second magnetron positioned adjacent the second backing plate, the second magnetron spaced a second distance from the second backing plate, the first distance is greater than the second distance.

2. The apparatus of claim 1, wherein the first magnetron and the second magnetron comprise different racetrack patterns.

3. A physical vapor deposition apparatus, comprising:
a first sputtering target assembly having a first sputtering target and a first backing plate coupled therewith;
a first magnetron positioned adjacent first backing plate, the first magnetron having a first size;
a second sputtering target assembly having a second sputtering target and a second backing plate coupled therewith; and
a second magnetron positioned adjacent the second backing plate, the second magnetron having a second size, the first size is greater than the second size.

4. The apparatus of claim 3, wherein the first magnetron is spaced a greater distance away from the first backing plate than the second magnetron is spaced from the second backing plate.

5. A physical vapor deposition apparatus, comprising:
a first sputtering target assembly having a first sputtering target and a first backing plate coupled therewith;
a first magnetron positioned adjacent first backing plate, the first magnetron configured to create a first magnetic track pattern;
a second sputtering target assembly having a second sputtering target and a second backing plate coupled therewith; and
a second magnetron positioned adjacent the second backing plate, the second magnetron configured to create a second magnetic track pattern, the first magnetic track pattern is different from the second magnetic track pattern.

6. The apparatus of claim 5, wherein the first magnetron is spaced a greater distance away from the first backing plate than the second magnetron is spaced from the second backing plate.

7. A physical vapor deposition apparatus, comprising:
a first sputtering target assembly having a first sputtering target and a first backing plate coupled therewith;
a first magnetron positioned adjacent first backing plate, the first magnetron having a first pitch;
a second sputtering target assembly having a second sputtering target and a second backing plate coupled therewith; and
a second magnetron positioned adjacent the second backing plate, the second magnetron having a second pitch, the first pitch is different from the second pitch.

8. The apparatus of claim 7, wherein the first magnetron is spaced a greater distance away from the first backing plate than the second magnetron is spaced from the second backing plate.

9. A physical vapor deposition apparatus, comprising:
a first sputtering target assembly having a first sputtering target and a first backing plate coupled therewith;
a first magnetron positioned adjacent first backing plate, the first magnetron having a first magnitude;
a second sputtering target assembly having a second sputtering target and a second backing plate coupled therewith; and
a second magnetron positioned adjacent the second backing plate, the second magnetron having a second magnitude, the first magnitude is different from the second magnitude.

10. The apparatus of claim 9, wherein the first magnetron is spaced a greater distance away from the first backing plate than the second magnetron is spaced from the second backing plate.

11. A sputtering method, comprising:
positioning first and second target assemblies in a sputtering chamber, each target assembly having a sputtering target with a sputtering surface;
creating a first magnetic field, the first magnetic field extending a first distance past the first sputtering surface;
creating a second magnetic field, the second magnetic field extending a second distance past the second sputtering surface, the second distance is shorter than the first distance; and
applying a bias to the first and second sputtering target assemblies to sputter material.

12. The method of claim 11, further comprising:
moving the first magnetic field and the second magnetic field.

13. A sputtering method, comprising:
positioning first and second target assemblies in a sputtering chamber, each sputtering target assembly having a sputtering target with a sputtering surface;
moving a first magnetron a first distance, the first magnetron positioned behind the first sputtering target assembly;
moving a second magnetron a second distance, the second magnetron positioned behind the second target assembly, the first distance is greater than the second distance; and
applying a bias to the first and second sputtering target assemblies to sputter material.

14. The method of claim 13, wherein the first magnetron and the second magnetron each comprise a racetrack pattern, and wherein the racetrack patterns are different.

15. A sputtering method, comprising:
positioning first and second target assemblies in a sputtering chamber, each target assembly having a sputtering target with a sputtering surface;
creating a first magnetic field track across the first sputtering surface;
creating a second magnetic field track across the second sputtering surface, the first magnetic field track and the second magnetic field track each have different shapes; and
applying a bias to the first and second sputtering target assemblies to sputter material.

16. The method of claim 15, further comprising:
moving the first magnetic field track and the second magnetic field track.

17. A sputtering method, comprising:
positioning first and second target assemblies in a sputtering chamber, each target assembly having a sputtering target with a sputtering surface;
creating a first magnetic field, the first magnetic field having a first pitch;
creating a second magnetic field, the second magnetic field having a second pitch, the second pitch is shorter than the first pitch; and
applying a bias to the first and second sputtering target assemblies to sputter material.

18. The method of claim 17, further comprising:
moving the first magnetic field and the second magnetic field.

19. A sputtering method, comprising:
positioning first and second target assemblies in a sputtering chamber, each target assembly having a sputtering target with a sputtering surface;
creating a first magnetic field, the first magnetic field having a first magnitude;
creating a second magnetic field, the second magnetic field having a second magnitude, the second magnitude is less than the first magnitude; and
applying a bias to the first and second sputtering target assemblies to sputter material.

20. The method of claim 19, further comprising:
moving the first magnetic field and the second magnetic field.
